(19) United States
(12) Patent Application Publication
(10) Pub. No.: US 2022/0085793 A1
(43) Pub. Date: Mar. 17, 2022

(54) INTEGRATED STRUCTURE OF CRYSTAL RESONATOR AND CONTROL CIRCUIT AND INTEGRATION METHOD THEREFOR

(71) Applicant: NINGBO SEMICONDUCTOR INTERNATIONAL CORPORATION (SHANGHAI BRANCH), Shanghai (CN)

(72) Inventor: Xiaoshan QIN, Ningbo, Zhejiang (CN)

(21) Appl. No.: 17/419,683

(22) PCT Filed: Nov. 5, 2019
(86) PCT No.: PCT/CN2019/115642

§ 371 Date: Jun. 29, 2021

(30) Foreign Application Priority Data
Dec. 29, 2018 (CN) 201811643104.9

(51) Int. Cl. H03H 9/205; H03H 9/19; H03H 3/02; H01L 27/20

(52) U.S. Cl. CPC H03H 9/205; H01L 27/20; H03H 3/02; H03H 9/19

(57) ABSTRACT

A method for integrating a crystal resonator with a control circuit and an integrated structure thereof. Integration of the crystal resonator with the control circuit (110) is accomplished by forming a lower cavity (120) in a device wafer (100) containing the control circuit (110) and an upper cavity (310) in a substrate (300), and by bonding the substrate (300) to the device wafer (100) in such a manner that the piezoelectric vibrator is sandwiched between the device wafer (100) and the substrate (300). A semiconductor die (700) can be further bonded to a back side of the same device wafer (100). This results in an increased degree of integration of the crystal resonator and allows on-chip modulation of its parameters. This crystal resonator is more compact in size, less power-consuming and easier to integrate with other semiconductor components with a higher degree of integration, compared with traditional crystal resonators.

### TECHNICAL FIELD

The present invention relates to the technical field of semiconductor and, in particular, to an integrated structure of crystal resonator and control circuit and an integration method therefor.

### BACKGROUND

A crystal resonator is a device operating on the basis of inverse piezoelectricity of a piezoelectric crystal. As key components in crystal oscillators and filters, crystal resonators have been widely used to create high-frequency electrical signals for performing precise timing, frequency referencing, filtering and other frequency control functions that are necessary for measurement and signal processing systems.

The continuous development of semiconductor technology and increasing popularity of integrated circuits has brought about a trend toward miniaturization of various semiconductor components. However, it is difficult to integrate existing crystal resonators with other semiconductor components, and also the sizes of the existing crystal resonators are relatively large.

For example, commonly used existing crystal resonators include surface-mount ones, in which a base is bonded with a metal solder (or an adhesive) to a cover to form a hermetic chamber in which a piezoelectric vibrator is housed. In addition, electrodes for the piezoelectric vibrator are electrically connected to an associated circuit via solder pads or wires. Further shrinkage of such crystal resonators is difficult, and their electrical connection to the associated circuit by soldering or gluing additionally hinders their miniaturization.

### SUMMARY OF THE INVENTION

It is an object of the present invention to provide a method for integrating a crystal resonator with a control circuit, which overcomes the above described problems with conventional crystal resonators, i.e., a bulky size and difficult integration.

To solve the problem, the present invention provides a method for integrating a crystal resonator with a control circuit according to the present invention, which comprises:

providing a device wafer containing the control circuit;

forming, in the device wafer, a lower cavity with an opening at a back side of the device wafer;

providing a substrate and etching it so that an upper cavity for the crystal resonator is formed therein at a location corresponding to the lower cavity;

forming a piezoelectric vibrator comprising a top electrode, a piezoelectric crystal and a bottom electrode, which are formed either on the back side of the device wafer or on the substrate;

forming a first connecting structure on the device wafer or on the substrate;

bonding the substrate to the back side of the device wafer such that the piezoelectric vibrator is positioned between the device wafer and the substrate, with the upper and lower cavities being located on opposing sides of the piezoelectric vibrator, and electrically connecting both the top and bottom electrodes of the piezoelectric vibrator to the control circuit through the first connecting structure; and

bonding a semiconductor die in a direction toward the back side of the device wafer and forming a second connecting structure that electrically connects the semiconductor die to the control circuit.

It is a further object of the present invention to provide an integrated structure of a crystal resonator and a control circuit, comprising:

a device wafer in which the control circuit and a lower cavity are formed, the lower cavity having an opening at a back side of the device wafer;

a substrate, which is bonded to the device wafer from the back side thereof, and in which an upper cavity is formed, the upper cavity having an opening arranged in opposition to the opening of the lower cavity;

a piezoelectric vibrator comprising a top electrode, a piezoelectric crystal and a bottom electrode, the piezoelectric vibrator arranged between the device wafer and the substrate so that the lower and upper cavities are on opposing sides of the piezoelectric vibrator;

a first connecting structure electrically connecting the top and bottom electrodes of the piezoelectric vibrator to the control circuit;

a semiconductor die bonded to the back side of the device wafer or to the substrate; and

a second connecting structure electrically connecting the semiconductor die to the control circuit.

In the method for integrating a crystal resonator with a control circuit according to the present invention, planar fabrication processes are utilized to form the lower cavity in the device wafer containing the control circuit and expose the lower cavity from the back side of the device wafer. As a result, the piezoelectric vibrator is allowed to be formed on the back side of the device wafer, accomplishing the integration of the crystal resonator with the control circuit on the same device wafer. Moreover, the semiconductor die is further bonded to the back side of the device wafer, thereby significantly increasing a degree of integration of the crystal resonator and enhancing its performance by allowing on-chip modulation of its parameters (e.g., for correcting raw deviations such as temperature and frequency drifts).

Therefore, in addition to being able to integrate with other semiconductor components with a higher degree of integration, the proposed crystal resonator is more compact, miniaturized in size, less costly and less power-consuming, compared with traditional crystal resonators (e.g., surface-mount ones).

### BRIEF DESCRIPTION OF THE DRAWINGS

FIG. 1 shows a flowchart schematically illustrating a method for integrating a crystal resonator according to an embodiment of the present invention.

FIGS. 2a to 2m are schematic representations of structures resulting from steps in a method for integrating a crystal resonator according to an embodiment of the present invention.

FIGS. 3a to 3d are schematic representations of structures resulting from steps in a method for integrating a crystal resonator with a control circuit according to Embodiment 3 of the present invention.

FIGS. 4a to 4d are schematic representations of structures resulting from steps in a method for integrating a crystal resonator with a control circuit according to Embodiment 4 of the present invention.

FIG. 5 is a schematic illustration of an integrated structure of a crystal resonator and a control circuit according to an embodiment of the present invention.

In these figures,

100 denotes a device wafer; AA, a device area; 100U, a front side; 100D, a back side; 100A, a substrate wafer; 100B, a dielectric layer; 110, a control circuit; 111, a first circuit; 111a, a first interconnecting structure; 111b, a third interconnecting structure; 112, a second circuit; 112a, a second interconnecting structure; 112b, a fourth interconnecting structure; 120, a lower cavity; 211b, a third conductive plug; 212b, a fourth conductive plug; 211a, a first conductive plug; 212a, a second conductive plug; 221b, a third connecting wire; 222b, a fourth connecting wire; 221a, a first connecting wire; 222a, a second connecting wire; 230, a fifth conductive plug; 410, a first encapsulation layer; 420, a second encapsulation layer; 400, a support wafer; 500, a piezoelectric vibrator; 510, a bottom electrode; 520, a piezoelectric crystal; 530, a top electrode; 600, a planarized layer; 700, a semiconductor die; 710, a first contact plug; 720, a second contact plug; and 710′, a contact pad.

### DETAILED DESCRIPTION

The core idea of the present invention is to provide a method for integrating a crystal resonator with a control circuit and an integrated structure thereof, in which planar fabrication processes are utilized to integrate the crystal resonator and a semiconductor die both on a device wafer where the control circuit is formed. This, on the one hand, results in a size reduction of the crystal resonator and, on the other hand, allows integration of the crystal resonator with other semiconductor components with an increased degree of integration.

Specific embodiments of the proposed structure and method will be described below in greater detail with reference to the accompanying drawings. Features and advantages of the invention will be more apparent from the following description. Note that the accompanying drawings are provided in a very simplified form not necessarily drawn to exact scale and for the only purpose of helping to explain the disclosed embodiments in a more convenient and clearer way.

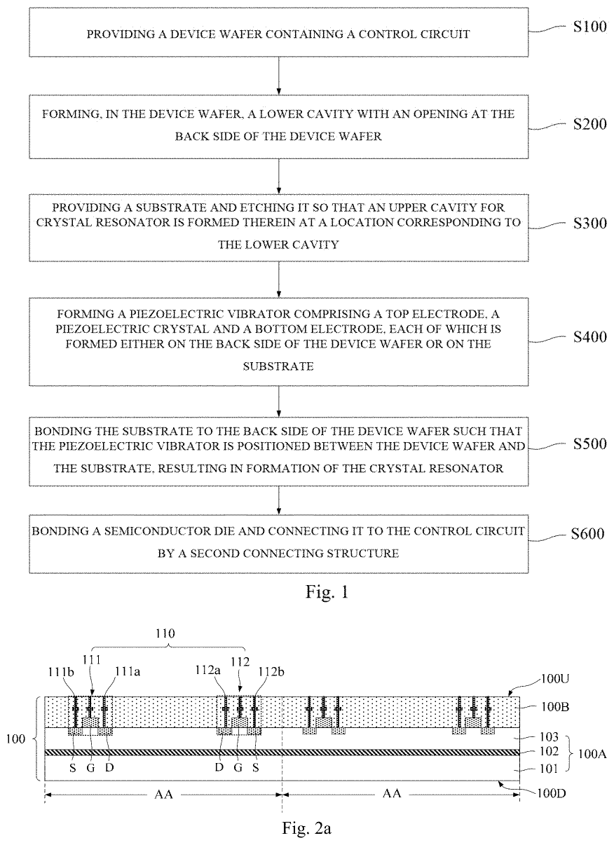

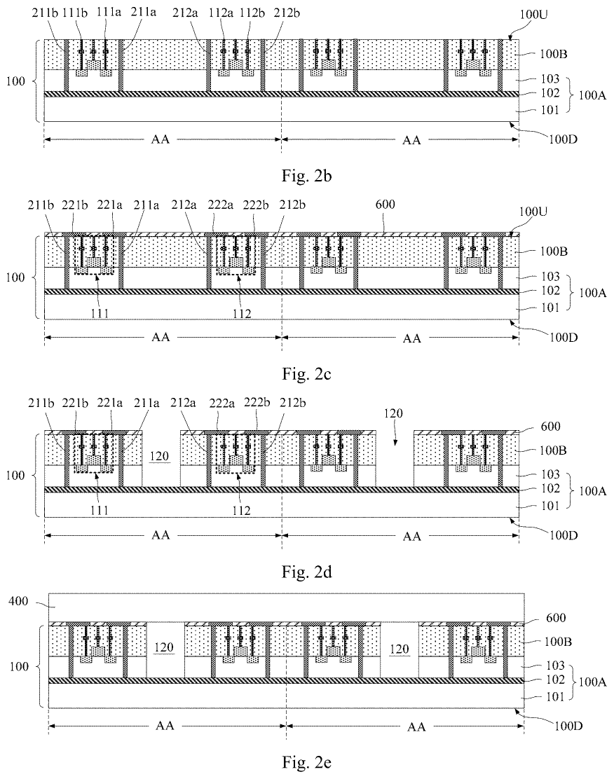

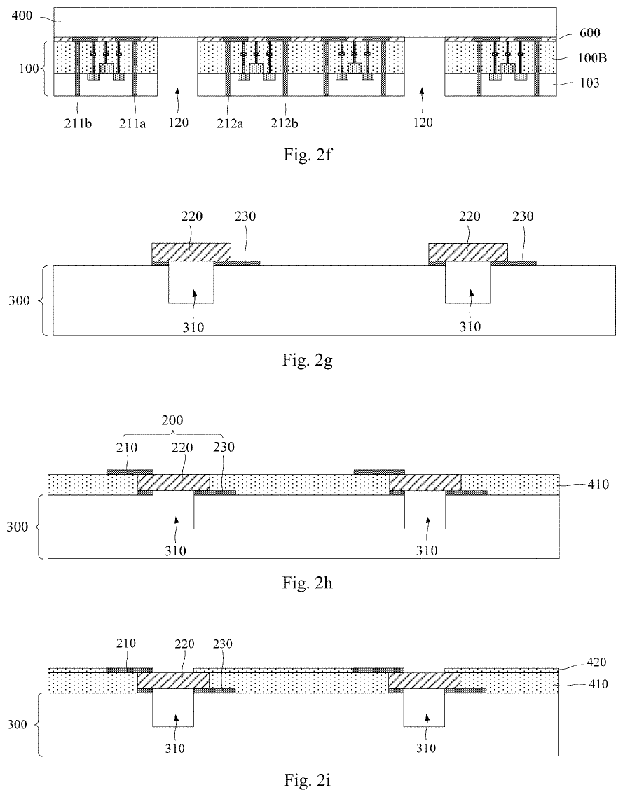

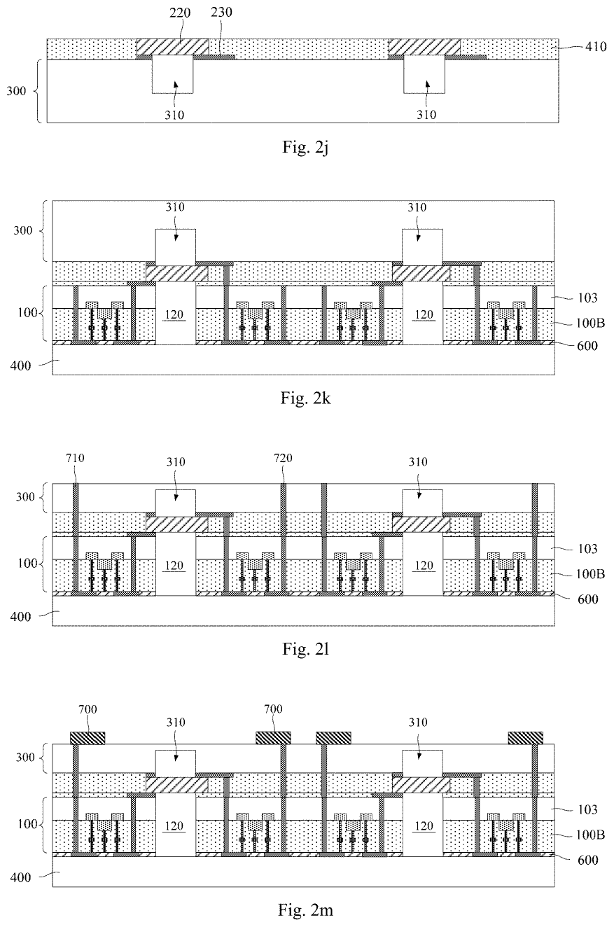

FIG. 1 shows a flowchart schematically illustrating a method for integrating a crystal resonator according to an embodiment of the present invention, and FIGS. 2a to 2l are schematic representations of structures resulting from steps in the method according to an embodiment of the present invention. In the following, steps for forming the crystal resonator will be described in detail with reference to the figures.

In step S100, with reference to FIG. 2a, a device wafer 100 is provided, in which a control circuit 110 is formed.

Specifically, the device wafer 100 has a front side 100U and an opposing back side 100D, and the control circuit 110 includes a plurality of interconnecting structure, at least some of which extend to the front side of the device wafer. The control circuit 110 may be configured to, for example, apply an electrical signal to the subsequently formed piezoelectric vibrator.

A plurality of crystal resonators may be formed on the single device wafer 100. Accordingly, there may be a plurality of device areas AA defined on the device wafer 100, with the control circuit 110 being formed in a corresponding one of the device areas AA.

The control circuit 110 may include a first circuit 111 and a second circuit 112, which may be electrically connected to a top electrode and a bottom electrode of the subsequently formed piezoelectric vibrator, respectively.

With continued reference to FIG. 2a, the first circuit 111 may include a first transistor, a first interconnecting structure 111a and a third interconnecting structure 111b. The first transistor may be buried in the device wafer 100, and the first and third interconnecting structures 111a, 111b may be both connected to the first transistor and extend to the front side of the device wafer 100. For example, the first interconnecting structure 111a may be connected to a drain of the first transistor, and the third interconnecting structure 111b to a source of the first transistor.

Similarly, the second circuit 112 may include a second transistor, a second interconnecting structure 112a and a fourth interconnecting structure 112b. The second transistor may be buried in the device wafer 100, and the second and fourth interconnecting structures 112a, 112b may be both connected to the second transistor and extend to the front side of the device wafer 100. For example, the second interconnecting structure 112a may be connected to a drain of the second transistor, and the fourth interconnecting structure 112b to a source of the second transistor.

In this embodiment, the device wafer 100 includes a substrate wafer 100A and a dielectric layer 100B on the substrate wafer 100A. Additionally, the first and second transistors may be both formed on the substrate wafer 100A and covered by the dielectric layer 100B. The third, first, second and fourth interconnecting structures 111b, 111a, 112a, 112b may be all formed within the dielectric layer 100B and extend to a surface of the dielectric layer 100B facing away from the substrate wafer.

The substrate wafer 100A may be either a silicon wafer or a silicon-on-insulator (SOI) wafer. In the latter case, the substrate wafer may include a base layer 101, a buried oxide layer 102 and a top silicon layer 103, which are sequentially stacked in this order in the direction from the back side 100D to the front side 100U.

It is to be noted that, in this embodiment, the interconnecting structures in the control circuit 110 extend to the front side 100U of the device wafer, while the piezoelectric vibrator is to be subsequently formed on, and the semiconductor die is to be subsequently bonded to, the back side 100D of the device wafer. Accordingly, first and second connecting structures may be subsequently formed to lead connection ports of the control circuit 110 from the front to back side of the device wafer and brought into electrical connection with the subsequently formed piezoelectric vibrator and semiconductor die.

Specifically, the first connecting structure may include a first connecting member for electrically connecting the first interconnecting structure 111a to the bottom electrode of the subsequently formed piezoelectric vibrator and a second connecting member for electrically connecting the second interconnecting structure 112a to the top electrode of the subsequently formed piezoelectric vibrator.

In addition, the first connecting member may include a first conductive plug 211a configured for electrical connection at its opposing ends respectively to the first interconnecting structure 111a and the subsequently formed bottom electrode. That is, the first conductive plug 211a may serve to lead a connecting port of the first interconnecting structure 111a in the control circuit from a front side of the control circuit to a back side of the control circuit so as to enable electrical connection of the bottom electrode subsequently formed on the back side of the device wafer to the control circuit from the back side of the control circuit.

Optionally, in this embodiment, the first connecting member may further include a first connecting wire 221a formed, for example, on the front side of the device wafer. The first connecting wire 221a may connect one end of the first conductive plug 211a to the first interconnecting structure, and the other end of the first conductive plug 221 may be electrically connected to the bottom electrode.

In alternative embodiments, the first connecting wire in the first connecting member may be formed on the back side of the device wafer. In this case, the first connecting wire may connect one end of the first conductive plug 211a to the bottom electrode, and the other end of the first conductive plug 211a may be electrically connected to the first interconnecting structure in the control circuit.

Similarly, the second connecting member may include a second conductive plug 212a configured for electrical connection at its opposing ends respectively to the second interconnecting structure 112a and the subsequently formed top electrode. That is, the second conductive plug 212a may serve to lead a connecting port of the second interconnecting structure 112a in the control circuit from the front to back side of the control circuit so as to enable electrical connection of the top electrode subsequently formed on the back side of the device wafer to the control circuit from the back side of the control circuit.

Additionally, in this embodiment, the second connecting member may further include a second connecting wire 222a formed, for example, on the front side of the device wafer. The second connecting wire 222a may connect one end of the second conductive plug 212a to the second interconnecting structure, and the other end of the second conductive plug 212a may be electrically connected to the top electrode.

In alternative embodiments, the second connecting wire in the second connecting member may be formed on the back side of the device wafer. In this case, the second connecting wire may connect one end of the second conductive plug 212a to the top electrode, and the other end of the second conductive plug 212a may be electrically connected to the second interconnecting structure in the control circuit.

The first conductive plug 211a in the first connecting member and the second conductive plug 212a in the second connecting member may be formed in a single process step. The first connecting wire 221a in the first connecting member and the second connecting wire 222a in the second connecting member may also be formed in a single process step.

The second connecting structure may also include conductive plugs and connecting wires. Likewise, the conductive plugs in the second connecting structure may extend through the device wafer, and the connecting wires in the second connecting structure may be formed, for example, on the front side of the device wafer and connect the conductive plugs to the control circuit. As such, the conductive plugs and connecting wires in the second connecting structure lead connection ports of the control circuit for connecting the semiconductor die from the front to back side of the device wafer. In this embodiment, the conductive plugs in the second connecting structure may include a third conductive plug 211b and a fourth conductive plug 212b, and the connecting wires in the second connecting structure may include a third connecting wire 221b and a fourth connecting wire 222b.

The first conductive plug 211a and first connecting wire 221a in the first connecting member, the second conductive plug 212a and second connecting wire 222a in the second connecting member, and the third conductive plug 211b, third connecting wire 221b, fourth conductive plug 212b and fourth connecting wire 222b in the second connecting structure may be formed in a single process including, for example, the steps as follows:

Step 1: Etching the device wafer 100 from the front side 100U thereof to form a first connecting hole, a second connecting hole, a third connecting hole and a fourth connecting hole therein. Specifically, all the first, second, third and fourth connecting holes may have a bottom that is closer to the back side 100D of the device wafer than a bottom of the control circuit.

Step 2: Filling a conductive material in the first, second, third and fourth connecting holes, resulting in the formation of the first, second, third and fourth conductive plugs 211a, 212a, 211b, 212b, as shown in FIG. 2b.

In this embodiment, all the first, second, third and fourth conductive plugs 211a, 212a, 211b, 212b have a bottom closer to the back side 100D of the device wafer than the control circuit. Specifically, the first and second transistors 111T, 112T may be both formed within the top silicon layer 103 above the buried oxide layer 102, while the first, second, third and fourth conductive plugs 211a, 212a, 211b, 212b may each penetrate sequentially through the dielectric layer 100B and the top silicon layer 103 and terminate at the buried oxide layer 102. Thus, it may be considered that the buried oxide layer 102 can serve as an etch stop layer for the etching process for forming the connecting holes. In this way, high etching accuracy can be achieved for the etching process.

Step 3: Forming, on the front side of the device wafer 100, the first connecting wire 221a that connects the first conductive plug 211a to the first interconnecting structure 111a, the second connecting wire 222a that connects the second conductive plug 212a to the second interconnecting structure 112a, the third connecting wire 221b that connects the third conductive plug 211b to the third interconnecting structure 111b, and the fourth connecting wire 222b that connects the fourth conductive plug 212b to the fourth interconnecting structure 112b, as shown in FIG. 2c.

In a subsequent process, the device wafer may be thinned from the back side so that the first, second, third and fourth conductive plugs 211a, 212a, 211b, 212b are exposed from the processed back side and brought into electrical connection with the piezoelectric vibrator and semiconductor die on the back side.

In embodiments with the first connecting wire in the first connecting member, the second connecting wire in the second connecting member and the connecting wires in the second connecting structure being all formed on the back side of the device wafer, the formation of the first connecting member that includes the first conductive plug and the first connecting wire, of the second connecting member that includes the second conductive plug and the second connecting wire and of the second connecting structure may include, for example:

first, forming a first connecting hole, a second connecting hole, a third connecting hole and a fourth connecting hole by etching the device wafer from the front side thereof;

then forming the first conductive plug that is electrically connected to the first interconnecting structure, the second conductive plug that is electrically connected to the second interconnecting structure, the third conductive plug that is electrically connected to the third interconnecting structure and the fourth conductive plug that is electrically connected to the fourth interconnecting structure by filling a conductive material into the first, second, third and fourth connecting holes;

subsequently, thinning the device wafer from the back side thereof so that the first, second, third and fourth conductive plugs are exposed; and

forming, on the back side of the device wafer, the first connecting wire that is connected to the first conductive plug at one end and configured for electrical connection with the bottom electrode at the other end, the second connecting wire that is connected to the second conductive plug at one end and configured for electrical connection with the top electrode at the other end, the third connecting wire that is connected to the third conductive plug at one end and configured for electrical connection with the semiconductor die at the other end, and the fourth connecting wire that is connected to the fourth conductive plug at one end and configured for electrical connection also with the semiconductor die at the other end.

It is to be noted that although the first, second, third and fourth conductive plugs 211a, 212a, 211b, 212b have been described above as being formed from the front side of the device wafer prior to the formation of the first, second, third and fourth connecting wires 221a, 222a, 221b, 222b, they may be alternatively formed from the back side of the device wafer subsequent to the thinning of the device wafer, as will be described in greater detail below.

In addition, in a subsequent process, a support wafer may be bonded to the front side 100U of the device wafer 100. Accordingly, subsequent to the formation of the first, second, third and fourth connecting wires 221a, 222a, 221b, 222b, the method may optionally further include forming, on the front side 100U of the device wafer 100, a planarized layer 600 which provides the device wafer 100 with a flatter bonding surface.

Specifically, referring to FIG. 2c, the planarized layer 600 may be formed on the front side 100U of the device wafer 100 and may have a top surface not lower than those of the first, second, third and fourth connecting wires 221a, 222a, 221b, 222b. For example, the planarized layer 600 may cover the device wafer 100 and the first, second, third and fourth connecting wires 221a, 222a, 221b, 222b so as to provide a flatter top surface. Alternatively, the top surface of the planarized layer 600 may also be flush with those of the first, second, third and fourth connecting wires 221a, 222a, 221b, 222b so that it also provides the device wafer 100 with a flatter bonding surface.

In this embodiment, the planarized layer 600 may be formed using a polishing process. In this case, for example, the first and second connecting wires 221a, 222a, may serve as a polish stop such that the top surface of the formed planarized layer 600 is flush with those of the first, second, third and fourth connecting wires 221a, 222a, 221b, 222b, and all these surfaces may make up a bonding surface for the device wafer 100.

In step S200, with reference to FIGS. 2d to 2f, a lower cavity 120 with an opening at the back side of the device wafer is formed in the device wafer 100.

In this embodiment, the lower cavity 120 may be formed, for example, using a method including steps S210 and S220 below.

In step S210, with reference to FIG. 2d, the lower cavity 120 of the crystal resonator is formed by etching the device wafer 100 from the front side thereof.

Specifically, the lower cavity 120 extends deep into the device wafer 100 from the front side 100U and may have a bottom that is closer to the back side 100D of the device wafer than the bottom of the control circuit 110.

In this embodiment, the lower cavity 120 may be formed by performing an etching process which proceeds sequentially through the planarized layer 600, the dielectric layer 100B and the top silicon layer 103 and stops at the buried oxide layer 102.

Thus, the buried oxide layer 102 may serve as an etch stop layer for both the etching process for forming the first, second, third and fourth connecting holes for the first, second, third and fourth conductive plugs 211a, 212a, 211b, 212b and the etching process for forming the lower cavity 120. As a result, bottoms of the resulting conductive plugs are at the same or similar level as that of the lower cavity 120. In this way, it can be ensured that the first, second, third and fourth conductive plugs 211a, 212a, 211b, 212b and the lower cavity 12 can be all exposed when the device wafer is subsequently thinned from the back side 100D.

It is to be noted that the relative positions of the lower cavity 120 and the first and second circuits shown in the figures are merely for illustration, and in practice, the arrangement of the first and second circuits may depend on the actual circuit layout requirements, without limiting the present invention.

In step S220, with reference to FIGS. 2e and 2f, the device wafer 100 is thinned from the back side 100D until the lower cavity 120 is exposed.

As noted above, the lower cavity 120 is bottomed at the buried oxide layer 102. Therefore, as a result of thinning the device wafer, the base layer 101 and the buried oxide layer 102 are sequentially stripped away, and the top silicon layer 103 and lower cavity 120 are both exposed. Moreover, in this embodiment, since the first, second, third and fourth conductive plugs 211a, 212a, 211b, 212b are all also bottomed at the buried oxide layer 102, the thinning of the device wafer also results in the exposure of the first, second, third and fourth conductive plugs 211a, 212a, 211b, 212b, which allows these conductive plugs to be brought into electrical connection to the subsequently formed piezoelectric vibrator and to the semiconductor die.

Optionally, with reference to FIG. 2e, before the device wafer 100 is thinned, a support wafer 400 may be bonded to the front side of the device wafer 100, which can provide a support for the thinning process. Additionally, the support wafer 400 can close the opening of the lower cavity exposed at the front side of the device wafer. Therefore, it can be considered that, in this embodiment, the support wafer 400 also serves as a cap substrate for closing the opening of the lower cavity at the front side of the device wafer.

It is to be noted that, in this embodiment, the lower cavity 120 is formed by etching the device wafer 100 from the front side and thinning the device wafer 100 from the back side so that the opening of the lower cavity 120 is exposed at the back side of the device wafer 100.

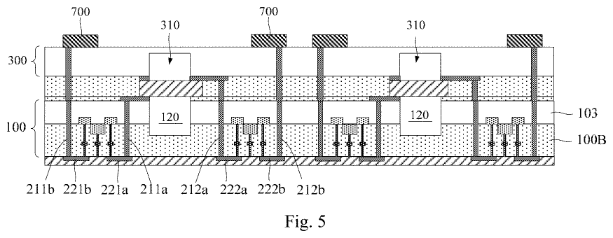

However, referring to FIG. 5, in other embodiments, the lower cavity 120 of the crystal resonator may be alternatively formed by etching the device wafer from the back side. In still other embodiments, the etching process on the back side of the device wafer may be preceded by a thinning of the device wafer.

With particular reference to FIG. 5, in one specific embodiment, the formation of the lower cavity by etching the device wafer from the back side thereof may include, for example, the following steps.

At first, the device wafer is thinned from the back side. In case of the substrate wafer being a SOI wafer, this may involve sequential removal of the base layer and the buried oxide layer of the substrate wafer. Of course, the thinning of the substrate wafer may alternatively involve partial removal of the base layer, complete removal of the base layer and hence exposure of the buried oxide layer, or the like.

Next, the device wafer is etched from the back side so that the lower cavity is formed. It is to be noted that the lower cavity resulting from the etching of the device wafer may have a depth as practically required, and the present invention is not limited to any particular depth of the lower cavity. For example, after the device wafer is thinned and the top silicon layer 103 is exposed, the top silicon layer 103 may be etched to form the lower cavity therein. Alternatively, the etching process may proceed through the top silicon layer 103 and further into the dielectric layer 100B, so that the resulting lower cavity 120 extends from the top silicon layer 103 down into the dielectric layer 100B.

It is to be also noted that during the formation of the lower cavity as shown in FIG. 5, prior to the formation of the lower cavity, another support wafer may be optionally bonded to the front side of the device wafer to enhance support for the device wafer. Of course, instead of bonding the support wafer, it is also plausible to form a encapsulation layer on the front side of the device wafer, which covers all the components exposed on the front side of the device wafer.

As discussed above, in other embodiments, the thinning of the device wafer may be followed by forming the first conductive plug 211a in the first connecting member, the second conductive plug 212a in the second connecting member and the third and fourth conductive plugs 211b, 212b in the second connecting structure from the back side of the device wafer 100.

Specifically, a method for forming the aforementioned connecting wires on the front side of the device wafer 100, forming the above conductive plugs from the back side of the device wafer 100, and connecting the conductive plugs to the respective connecting wires may include the steps below.

At first, prior to the bonding of the support wafer 400, the first, second, third and fourth connecting wires 221a, 222a, 221b, 222b are formed on the front side of the device wafer 100.

Wherein, the first connecting wire 221a is electrically connected to the first interconnecting structure 111a, the second connecting wire 212a to the second interconnecting structure 112a, the third connecting wire 221b to the third interconnecting structure 111b and the fourth connecting wire 212b to the fourth interconnecting structure 112b.

Next, after the device wafer 100 is thinned, it is etched from the back side to form therein first, second, third and fourth connecting holes, all of which extend through the device wafer 100 so that the first, second, third and fourth connecting wires 221a, 222a, 221b, 222b are exposed respectively in the holes.

Subsequently, a conductive material is filled in the first, second, third and fourth connecting holes, resulting in the formation of the first, second, third and fourth conductive plugs 211a, 212a, 211b, 212b.

Wherein, the first conductive plug 211a is connected at one end to the first connecting wire 221a and configured for electrical connection with the bottom electrode of the piezoelectric vibrator at the other end. The second conductive plug 212a is connected at one end to the second connecting wire 222a and configured for electrical connection with the top electrode of the piezoelectric vibrator at the other end. The third conductive plug 211b is connected at one end to the third connecting wire 221b and configured for electrical connection with the semiconductor die at the other end. The fourth conductive plug 212b is connected at one end to the fourth connecting wire 222b and configured for electrical connection also with the semiconductor die at the other end.

In an alternative embodiment, a method for forming the aforementioned connecting wires on the back side of the device wafer 100, forming the above conductive plugs from the back side of the device wafer 100, and connecting the conductive plugs to the respective connecting wires may include the steps below.

At first, the device wafer 100 is thinned from the back side, followed by etching the device wafer 100 from the back side and thus forming first, second, third and fourth connecting holes.

Next, a conductive material is filled in the first, second, third and fourth connecting holes, resulting in the formation of the first, second, third and fourth conductive plugs. The first conductive plug is electrically connected at one end to the first interconnecting structure, and the second conductive plug is electrically connected at one end to the second interconnecting structure. The third conductive plug is electrically connected at one end to the third interconnecting structure, and the fourth conductive plug is electrically connected at one end to the fourth interconnecting structure.

Subsequently, the first, second, third and fourth connecting wires are formed on the back side of the device wafer 100. One end of the first connecting wire is connected to the other end of the first conductive plug, and the other end of the first connecting wire is configured for electrical connection with the bottom electrode. One end of the second connecting wire is connected to the other end of the second conductive plug, and the other end of the second connecting wire is configured for electrical connection with the top electrode. One end of the third connecting wire is connected to the third conductive plug, and the other end of the third connecting wire is configured for electrical connection with the semiconductor die. One end of the fourth connecting wire is connected to the fourth conductive plug, and the other end of the fourth connecting wire is configured for electrical connection also with the semiconductor die.

In step S300, with reference to FIG. 2g, a substrate 300 is provided and etched so that an upper cavity 310 of the crystal resonator is formed therein in positional correspondence with the lower cavity 120. In a subsequent process for bonding the substrate 300 to the device wafer 100, the upper and lower cavities 310, 120 may be positioned in positional correspondence with each other on opposing sides of the piezoelectric vibrator.

On the substrate 300, there may be also defined a plurality of device areas AA corresponding to those on the device wafer 100, and the lower cavity 120 may be formed in the corresponding one of the device areas AA on the device wafer 100.

In step S400, a piezoelectric vibrator including a top electrode, a piezoelectric crystal and a bottom electrode is formed. Each of the top electrode, the piezoelectric crystal and the bottom electrode may be formed either on the back side of the device wafer 100 or on the substrate 300.

In other words, it is possible that the top electrode, the piezoelectric crystal and the bottom electrode in the piezoelectric vibrator are all formed on the back side of the device wafer 100, or on the substrate 300. It is also possible that the bottom electrode of the piezoelectric vibrator is formed on the back side of the device wafer, with the top electrode and piezoelectric crystal of the piezoelectric vibrator being formed successively on the substrate 300. It is still possible that the bottom electrode and the piezoelectric crystal of the piezoelectric vibrator are formed successively on the back side of the device wafer, with the top electrode of the piezoelectric vibrator being formed on the substrate 300.

In this embodiment, the top electrode, piezoelectric crystal and bottom electrode in the piezoelectric vibrator are all formed on the substrate 300. Specifically, a method for forming the piezoelectric vibrator on the substrate 300 may include the steps as follows:

Step 1: Forming the top electrode 530 at a predetermined location on a surface of the substrate 300, as shown in FIG. 2g. In this embodiment, the top electrode 530 surrounds the upper cavity 310. In a subsequent process, the top electrode 530 may be brought into electrical connection with the control circuit 110 and, more exactly, to the second interconnecting structure in the second circuit 112.

Step 2: With continued reference to FIG. 2g, bonding the piezoelectric crystal 520 to the top electrode 530. In this embodiment, the piezoelectric crystal 520 is located above the upper cavity 310, with its peripheral edge portions residing on the top electrode 530. The piezoelectric crystal 520 may be, for example, a quartz crystal plate.

In this embodiment, the upper cavity 310 may be narrower than the piezoelectric crystal 520 so that the piezoelectric crystal 520 can be arranged with its peripheral edge portions residing on the surface of the substrate, thus covering an opening of the upper cavity 310.

However, in other embodiments, the upper cavity may be made up of, for example, a first portion and a second portion. The first portion may be located more deeply in the substrate than the second portion, and the second portion may be adjacent to the surface of the substrate. Additionally, the first portion may be narrower than the piezoelectric crystal 520, and the second portion may be broader than the piezoelectric crystal. In this way, the piezoelectric crystal 520 may be at least partially received in the second portion, with its peripheral edge portions residing on top edges of the first portion. In addition, it is devisable that the opening of the upper cavity is wider than the piezoelectric crystal.

Further, the top electrode 530 may have an extension laterally extending beyond the piezoelectric crystal 520 thereunder. In a subsequent process, the top electrode 530 may be connected to the second interconnecting structure in the second circuit 112 via the extension.

Step 3: Forming the bottom electrode 510 on the piezoelectric crystal 520, as shown in FIG. 2h. The bottom electrode 510 may be so formed that a central portion of the piezoelectric crystal 520 is exposed therefrom. In a subsequent process, the bottom electrode 510 may be electrically connected to the control circuit 110 and, more exactly, to the first interconnecting structure in the first circuit 111.

Thus, in the control circuit 110, the first circuit 111 is electrically connected to the bottom electrode 510, and the second circuit 112 is electrically connected to the top electrode 530. As such, an electrical signal can be applied to the bottom and top electrodes 510, 530 to create an electric field therebetween, which causes the piezoelectric crystal 520 between the top and bottom electrodes 530, 510 to change its shape. The magnitude of the shape change of the piezoelectric crystal 520 depends on the strength of the electric field, and when the electric field between the top and bottom electrodes 530, 510 is inverted, the piezoelectric crystal 520 will responsively change its shape in the opposite direction. Therefore, when the control circuit 110 applies an AC signal to the top and bottom electrodes 530, 510, the piezoelectric crystal 520 will change shape alternately in opposite directions and thus alternately contract and expand due to the change in direction of the electric field. As a result, the piezoelectric crystal 520 will vibrate mechanically.

In this embodiment, a method for forming the bottom electrode 510 on the substrate 300 may include, for example, the steps below.

In a first step, with reference to FIG. 2h, a first encapsulation layer 410 is formed on the substrate 300, which covers the substrate 300, and from which the piezoelectric crystal 520 is exposed. It is to be noted that, in this embodiment, since the top electrode 530 is formed under the piezoelectric crystal 520, with the extension thereof extending laterally beyond the piezoelectric crystal 520, the first encapsulation layer 410 also covers the extension of the top electrode 530.

In addition, a top surface of the first encapsulation layer 410 may not be higher than that of the piezoelectric crystal 520. In this embodiment, the formation of the first encapsulation layer 410 may involve planarizing the first encapsulation layer 410 so that its top surface is flush with that of the piezoelectric crystal 520.

In a second step, with continued reference to FIG. 2h, the bottom electrode 510 is formed on the surface of the piezoelectric crystal 520. The bottom electrode 510 has an extension extending laterally beyond the piezoelectric crystal 520 over the first encapsulation layer 410. In a subsequent process, the bottom electrode 510 may be connected to the control circuit (more exactly, to the first interconnecting structure in the first circuit 111) via the extension.

The bottom and top electrodes 510, 530 may be successively formed, using a thin-film deposition or vapor deposition process, each of a material including silver.

It is to be noted that, in this embodiment, the top electrode 530, the piezoelectric crystal 520 and the bottom electrode 510 are successively formed over the substrate 300 using semiconductor processes. However, in other embodiments, it is also possible to form the top and bottom electrodes on opposing sides of the piezoelectric crystal and then bond the three as a whole onto the substrate.

Optionally, subsequent to the formation of the bottom electrode 510, the method may further include forming a second encapsulation layer on the first encapsulation layer 410, which provides the substrate 300 with a fatter surface that is favorable to the subsequent bonding process.

With reference to FIG. 2i, the second encapsulation layer 420 formed on the first encapsulation layer 410 may have a top surface not higher than that of the bottom electrode 510 so that the bottom electrode 510 remains exposed. In this embodiment, the formation of the second encapsulation layer 420 may involve planarizing the second encapsulation layer 420 so that its top surface is flush with that of the bottom electrode 510. Moreover, the central portion of the piezoelectric crystal 520 may also be exposed from the second encapsulation layer 420. In this way, when the substrate 300 is subsequently bonded to the device wafer 100, the central portion of the piezoelectric crystal 520 is in positional correspondence with the lower cavity 120 in the device wafer 100.

Subsequently, a fifth conductive plug 230 of the second connecting member in the first connecting structure may be formed on the device wafer 100 or on the substrate 300. In a subsequent process, the bottom electrode 510 may be brought into electrical connection with the control circuit in the device wafer 100 by means of the first conductive plug and first connecting wire in the first connecting member, and the top electrode 530 on the substrate 300 may be brought into electrical connection with the control circuit in the device wafer 100 by means of the second conductive plug, second connecting wire and fifth conductive plug 230 in the second connecting member.

Specifically, with combined reference to FIGS. 2i and 2f, in this embodiment, the bottom electrode 510 with its aforementioned extension is exposed at the surface of the second encapsulation layer 420, and the first conductive plug 211a is exposed at the top at the surface of the device wafer 100. Therefore, the device wafer 100 and the substrate 300 may be so bonded together that the bottom electrode 510 resides on the surface of the device wafer 100, with a connecting member being established between its extension and the first conductive plug 211a.

Referring to FIGS. 2i and 2f, the extension of the top electrode 530 that is buried within the first encapsulation layer 410 may be brought into electrical connection with the second conductive plug 212a by the fifth conductive plug.

In this embodiment, subsequent to the successive formation of the top electrode 530 and the piezoelectric crystal 520 on the substrate 300, the fifth conductive plug of the second connecting member may be formed on the substrate 300, in particular, using a method including the steps below.

At first, a encapsulation layer is formed on the surface of the substrate 300. In this embodiment, this encapsulation layer is made up of the aforementioned first and second encapsulation layers 410, 420.

Next, with reference to FIG. 2j, a through hole is formed in the encapsulation layer, in which the top electrode 530 is exposed, and a conductive material is filled in the through hole, resulting in the formation of the fifth conductive plug 230, which is electrically connected at one end to the top electrode 530, in particular, to the extension of the top electrode 530.

In this embodiment, the through hole extends sequentially through the second encapsulation layer 420 and the first encapsulation layer 410, and the fifth conductive plug 230 is then formed by filling a conductive material in the through hole. One end of the fifth conductive plug 230 is electrically connected to the top electrode 530, and the other end thereof is exposed at the surface of the second encapsulation layer 420. As such, an electrical connection can be created between the other end of the fifth conductive plug 230 and the second conductive plug 212a as a result of bonding the substrate 300 to the device wafer 100.

In step S500, with reference to FIG. 2k, the substrate 300 is bonded to the back side of the device wafer 100 such that the piezoelectric vibrator 500 is sandwiched between the device wafer 100 and the substrate 300, with the upper and lower cavities 310, 120 being located on opposing sides of the piezoelectric vibrator 500, resulting in the formation of the crystal resonator. In addition, the top and bottom electrodes 530, 510 of the piezoelectric vibrator 500 are both electrically connected to the control circuit through the first connecting structure.

As discussed above, in this embodiment, the device wafer 100 and the substrate 300 are so bonded that, in the control circuit, the first circuit 111 is electrically connected to the bottom electrode 510 by the first connecting member (including the first connecting wire and the first conductive plug) and the second circuit 112 is electrically connected to the top electrode 530 by the second connecting member (including the second connecting wire, the second conductive plug and the fifth conductive plug). In this way, the control circuit can apply an electrical signal to the electrodes sandwiching the piezoelectric crystal 520, which causes the piezoelectric crystal 520 to change its shape and vibrate in the upper and lower cavities 310, 120.

The bonding of the device wafer 100 and the substrate 300 may be accomplished by a method including, for example, applying adhesive layer(s) to the device wafer 100 and/or the substrate 300 and bonding the device wafer 100 and the substrate 300 together by means of the adhesive layer(s). Specifically, an adhesive layer may be applied to the substrate with the piezoelectric crystal formed thereon in such a manner that the surface of the piezoelectric crystal is exposed at a surface of the adhesive layer, and the substrate without the piezoelectric crystal formed thereon may be then bonded to the adhesive layer.

In this embodiment, the piezoelectric vibrator 500 is formed on the substrate 300. Accordingly, the bonding of the device wafer 100 and the substrate 300 may be accomplished by a method including, for example, applying an adhesive layer to the substrate 300 so that the surface of the piezoelectric vibrator 500 is exposed at a surface of the adhesive layer, and then bonding together the substrate 300 and the device wafer 100 by means of the adhesive layer.

Therefore, in this embodiment, the top electrode 530, piezoelectric crystal 520 and bottom electrode 510 of the piezoelectric vibrator 500 are all formed on the substrate 300, and the piezoelectric vibrator 500 covers an opening of the upper cavity 310. In addition, the bonding is so performed that the lower cavity 120 is located on the side of the piezoelectric vibrator 500 away from the upper cavity 310 and the crystal resonator is thus formed. In addition, the crystal resonator is electrically connected to the control circuit in the device wafer 100, achieving the integration of the crystal resonator with the control circuit.

In step S600, with reference to FIGS. 2l to 2m, a semiconductor die 700 is bonded in such a manner that it is electrically connected to the control circuit by the second connecting structure.

In the semiconductor die 700, for example, a drive circuit for providing an electrical signal may be formed. The electrical signal is applied by the control circuit to the piezoelectric vibrator 500 so as to control shape change thereof.

The semiconductor die 700 may be heterogeneous from the device wafer 100. That is, the semiconductor die 700 may include a substrate made of a material different from that of the device wafer 100. For example, in this embodiment, differing from the device wafer 100 that is made of silicon, the substrate of the heterogeneous die may be formed of a Group III-V semiconductor material or a Group II-VI semiconductor material (specific examples include germanium, germanium silicon, gallium arsenide, etc.)

In this embodiment, the semiconductor die 700 is bonded to the substrate 300 that has been bonded to the device wafer 100 and is brought into electrical connection with the control circuit by the second connecting structure.

As noted above, the second connecting structure may include conductive plugs (including the third and fourth conductive plugs) and connecting wires (including the third and fourth connecting wires), which lead connecting ports of the control circuit from the front to back side of the device wafer.

In this embodiment, since the semiconductor die 700 is bonded to the substrate 300 that has been bonded to the device wafer 100 and is brought into electrical connection with the control circuit by the second connecting structure, the second connecting structure may further include contact plugs which penetrate through the substrate 300 so as to come into electrical connection with the conductive plugs at the bottom and into electrical connection with the semiconductor die at the top.

The formation of the contact plugs in the second connecting structure may include the steps as follows.

Step 1: Forming contact holes by etching the substrate 300, as shown in FIG. 2l. In this embodiment, first and second connecting holes may be formed. Optionally, in order to facilitate the formation of the contact holes, the substrate 300 may be thinned before it is etched.

In this embodiment, each contact hole extends sequentially through the substrate 300, the first encapsulation layer 410 and the second encapsulation layer 420. The first contact hole extends from the substrate 300 up to the back side of the device wafer 100 so that the third conductive plug is exposed therein. The second contact hole extends from the substrate 300 up to the back side of the device wafer 100 so that the fourth conductive plug is exposed therein.

Step 2: Forming the contact plugs by filling a conductive material in the contact holes. The resulting conductive plugs are electrically connected to the control circuit at the bottom and are to be electrically connected to the semiconductor die 700 at the top. In this embodiment, a first contact plug 710 and a second contact plug 720 are formed by filling the conductive material in the first and second contact holes. The first contact plug 710 is electrically connected to the third conductive plug at the bottom, and the second contact plug 720 is electrically connected to the fourth conductive plug at the bottom.

The semiconductor die 700 may be bonded to the substrate 300 subsequent to the formation of the second connecting structure. In this embodiment, separate semiconductor dies 700 may be bonded respectively to the third and fourth contact plugs 710, 720. It will be recognized that, in other embodiments, contact pads may be formed on the substrate, in which cases, the contact pads may be connected to the tops of the contact plugs, and the semiconductor die 700 may be bonded to the contact pads.

In a subsequent process, the semiconductor die may be covered by a encapsulation layer formed over the substrate 300.

### Embodiment 2

Differing from Embodiment 1, the top electrode 530, piezoelectric crystal 520 and bottom electrode 510 of the piezoelectric vibrator 500 are all formed on the back side of the device wafer 100 and the piezoelectric vibrator 500 covers and closes an opening of the lower cavity 120 in accordance with Embodiment 2. In addition, after the crystal resonator is electrically connected to the control circuit in the device wafer 100, a bonding process is performed so that the upper cavity 310 is located on the side of the piezoelectric vibrator 500 away from the lower cavity 120. Forming the crystal resonator in this way also achieves integration of the crystal resonator with the control circuit.

Reference can be made to the description of Embodiment 1 for details in the provision of the device wafer containing the control circuit and the formation of the lower cavity in the device wafer, and these are not described here again for the sake of brevity.

In this embodiment, the formation of the piezoelectric vibrator 500 on the device wafer 100 may include the steps below.

At first, the bottom electrode 510 is formed at a predetermined location on the back side of the device wafer 100. In this embodiment, the bottom electrode 510 is positioned around the lower cavity 120.

Then, the piezoelectric crystal 520 is bonded to the bottom electrode 510. In this embodiment, the piezoelectric crystal 520 is so bonded above the lower cavity 120 that it covers and closes an opening of the lower cavity 120, with its peripheral edge portions residing on the bottom electrode 510.

Next, the top electrode 530 is formed on the piezoelectric crystal 520.

Of course, in other embodiments, it is also possible to form the top and bottom electrodes respectively on the opposing sides of the piezoelectric crystal and then bond the three as a whole to the back side of the device wafer 100.

Thereafter, the first connecting structure including the first connecting member for electrical connection to the bottom electrode and the second connecting member for electrical connection to the top electrode is formed on the device wafer 100. The first connecting member includes the first conductive plug and first connecting wire, and the second connecting member includes the second conductive plug and second connecting wire. Reference can be made to the description of Embodiment 1 for details in the formation of the first conductive plug, the first connecting wire, the second conductive plug and the second connecting wire, and these are not described here again for the sake of brevity.

In addition, the second connecting member includes the fifth conductive plug 230, which may be formed subsequent to the formation of the piezoelectric crystal 520 and prior to the formation of the top electrode 530. A method for forming the fifth conductive plug prior to the formation of the top electrode may include the steps as follows:

Step 1: Forming an encapsulation layer on the back side of the device wafer 100. In this embodiment, the encapsulation layer covers the back side of the device wafer 100, with the piezoelectric crystal 520 being exposed therefrom.

Step 2: Forming a through hole in the encapsulation layer and fill a conductive material in the through hole, thereby resulting in the formation of the fifth conductive plug 230. The resulting fifth conductive plug 230 is electrically connected to the second interconnecting structure at the bottom and exposed from the encapsulation layer at the top.

Step 3: Forming the top electrode 530 on the device wafer 100 in such a manner that the top electrode 530 covers at least part of the piezoelectric crystal 520 and extends therefrom over the fifth conductive plug and thus come into electrical connection with the conductive plug. That is, the extension of the top electrode 530 extending beyond the piezoelectric crystal is directly electrically connected to the fifth conductive plug 230.

Alternatively, in step 3, after the top electrode 530 is formed on the piezoelectric crystal 520, an interconnecting wire may be formed on the top electrode 530, which extends beyond the top electrode over the fifth conductive plug. In this way, the top electrode is electrically connected to the fifth conductive plug via the interconnecting wire. That is, the electrical connection between the top electrode 530 and the fifth conductive plug is accomplished by the interconnecting wire.

The substrate 300 may be bonded to the device wafer 100 after the piezoelectric vibrator 200 has been formed on the device wafer 100 and after the upper cavity 310 has been formed in the substrate 300.

Specifically, the bonding of the device wafer 100 and the substrate 300 may include: applying an adhesive layer to the device wafer 100 in such a manner that the surface of the piezoelectric crystal is exposed from the adhesive layer; and then bonding the device wafer 100 and the substrate 300 together by means of the adhesive layer.

The bonding may be so carried out that the upper cavity in the substrate 300 is located on the side of the piezoelectric crystal 520 away from the lower cavity. The upper cavity may be broader than the piezoelectric crystal so that the piezoelectric crystal can be accommodated within the upper cavity.

Reference can be made to the description of Embodiment 1 for details in bonding the semiconductor die to the substrate in step S600 and in bringing the semiconductor die into electrical connection with the control circuit by the second connecting structure, and these are not described here again for the sake of brevity.

### Embodiment 3

Differing from Embodiments 1 and 2 in which the top electrode, piezoelectric crystal and bottom electrode of the piezoelectric vibrator are all formed either on the substrate or on the device wafer, in accordance with Embodiment 3, the top electrode and piezoelectric crystal are formed on the substrate, while the bottom electrode is formed on the device wafer.

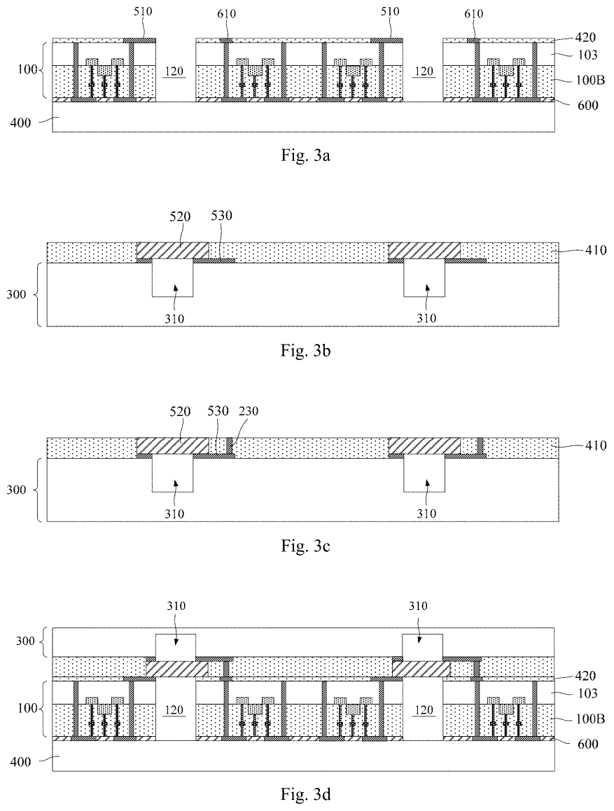

FIGS. 3a to 3d are schematic representations of structures resulting from steps in the method for integrating a crystal resonator with a control circuit according to the Embodiment 3 of the present invention. In the following, steps for forming the crystal resonator will be described in detail with reference to the figures.

Referring now to FIG. 3a, the device wafer 100 containing the control circuit is provided, and the bottom electrode 510 is formed on the back side of the device wafer 100 so that it is electrically connected to the first conductive plug in the first connecting structure.

During the formation of the bottom electrode 510, a rewiring layer 610 may be formed on the device wafer 100, which covers the second conductive plug in the first connecting structure.

Subsequent to the formation of the bottom electrode 510, the method may further include forming a second encapsulation layer 420 on the device wafer 100, which has a surface that is not higher than that of the bottom electrode 510 so that the bottom electrode 510 remains exposed. In this embodiment, the surface of the second encapsulation layer 420 is also not higher than that of the rewiring layer 610 so that the rewiring layer 610 is also exposed. In this way, the subsequent bonding process may be so performed that the bottom electrode 510 is positioned on one side of the piezoelectric crystal, with the rewiring layer 610 being electrically connected to the top electrode located on the other side of the piezoelectric crystal.

The formation of the second encapsulation layer 420 may involve a planarization process for making the surface of the second encapsulation layer 420 flush with that of the bottom electrode 510. In this way, a significant improved surface flatness can be provided to the device wafer 100, which is favorable to the subsequent bonding process.

With continued reference to FIG. 3a, in this embodiment, subsequent to the successive formation of the bottom electrode 510 and the second encapsulation layer 420, the lower cavity 120 can be formed by successively etching through the second encapsulation layer 420 and the dielectric layer 100B so that the bottom electrode 510 is positioned around the lower cavity 120.

Referring to FIG. 3b, the substrate 300 is provided and the top electrode 530 and piezoelectric crystal 520 are successively formed thereon above the upper cavity. The top electrode may be formed using a vapor deposition process or a thin-film deposition process, followed by bonding the piezoelectric crystal to the top electrode.

Specifically, the top electrode 530 is positioned around the upper cavity 310 and will be electrically connected to the rewiring layer 610 on the device wafer 100 and hence to the second interconnecting structure 112a in the second circuit 112 in a subsequent process. Moreover, the piezoelectric crystal 520 may be so positioned that a central portion thereof is in positional correspondence with the upper cavity 310 in the substrate 300, with its peripheral edge portions residing on top edges of the top electrode 530. Further, an extension of the top electrode 530 may extend beyond the piezoelectric crystal 520 thereunder.

With continued reference to FIG. 3b, in this embodiment, subsequent to the formation of the piezoelectric crystal 520, the method may further include forming a first encapsulation layer 410 on the substrate 300, which covers the substrate 300 and the extension of the top electrode 530. The first encapsulation layer 410 may have a surface not higher than that of the piezoelectric crystal 520 so that the piezoelectric crystal 520 is exposed therefrom.

Similarly, in this embodiment, the formation of the first encapsulation layer 410 may also involve a planarization process for making the surface of the first encapsulation layer 410 flush with that of the piezoelectric crystal 520. In this way, the substrate 300 may be provided with a flatter surface, which is favorable to the subsequent bonding process.

Subsequently, referring to FIG. 3c, the fifth conductive plug 230 of the first connecting structure is formed on the device wafer or in the substrate in order to electrically connect the top electrode 530 to the second conductive plug. The formation of the fifth conductive plug 230 may include the steps detailed below.

At first, an encapsulation layer is formed on the surface of the substrate 100. In this embodiment, the encapsulation layer is made up of the aforementioned first encapsulation layer 410.

Next, the encapsulation layer is etched so that a through hole is formed therein. In this embodiment, the first encapsulation layer 410 is etched, and the extension of the top electrode 530 is exposed in the resulting through hole. A conductive material is then filled in the through hole, resulting in the formation of the fifth conductive plug 230, which is exposed at the top from the surface of the first encapsulation layer 410. Specifically, the fifth conductive plug 230 is connected to the extension of the top electrode 530. As a result, the top electrode 530 is electrically connected to the second conductive plug via the fifth conductive plug 230 and the rewiring layer 610.

Afterward, referring to FIG. 3d, the substrate 300 is bonded to the back side of the device wafer so that the lower cavity 120 is positioned on the side of the piezoelectric crystal 520 away from the upper cavity 310. Accordingly, the bottom electrode 510 on the device wafer 100 is located on the side of the piezoelectric crystal 520 away from the top electrode 530.

In this embodiment, the bonding of the substrate 300 to the device wafer 100 may include: applying an adhesive layer to the substrate 300 in such a manner that the surface of the piezoelectric crystal 520 is exposed from the adhesive layer; and then bonding the device wafer and the substrate together by means of the adhesive layer.

Specifically, the bonding of the substrate 300 to the device wafer 100 may bring the rewiring layer 610 on the device wafer 100 that is connected to the second conductive plug into electrical contact with the fifth conductive plug 230 on the substrate 300 that is connected to the top electrode 530, achieving electrical connection of the top electrode 530 to the control circuit.

Reference can be made to the description of Embodiment 1 for details in subsequently bonding the semiconductor die to the back side of the device wafer and in subsequently bringing the semiconductor die into electrical connection with the control circuit, and these are not described here again for the sake of brevity.

### Embodiment 4

Differing from the preceding embodiments, the semiconductor die is bonded to the back side of the device wafer prior to the bonding of the device wafer and the substrate, and the semiconductor die is brought into electrical connection with the control circuit by the second connecting structure in accordance with Embodiment 4. Embodiment 4 is explained below in the context with the bottom electrode, piezoelectric crystal and top electrode of the piezoelectric vibrator being all formed on the device wafer.

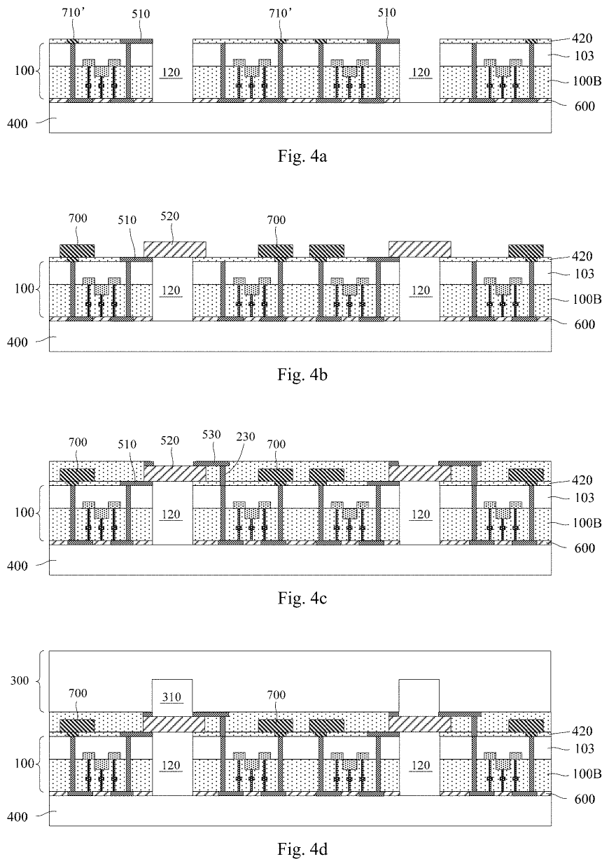

Referring now to FIG. 4a, the device wafer 100 is provided, which contains the control circuit, as well as the first conductive plug, first connecting wire, second conductive plug and second connecting wire in the first connecting structure and the conductive plugs and connecting wires in the second connecting structure.

With reference to FIGS. 4a to 4c, the bottom electrode 210, piezoelectric crystal 220 and top electrode 230 are successively formed on the device wafer 100.

In this embodiment, prior to the bonding of the substrate 300, the semiconductor die 700 is bonded to the device wafer 100.

Specifically, before the semiconductor die is bonded, the method may further include forming contact pads 710′ of the second connecting structure on the back side of the device wafer, which are electrically connected to the conductive plugs at the bottom and are to be electrically connected to the semiconductor die 700 at the top.

Subsequent to the bonding of the semiconductor die 700, an encapsulation layer is formed over the device wafer to cover the semiconductor die 700.

Further, in this embodiment, the first connecting structure further includes the fifth conductive plug 230 formed using a process including, for example, forming a through hole in the encapsulation layer by etching it, as shown in FIG. 4c, and filling a conductive material in the through hole. The fifth conductive plug 230 is electrically connected to the second conductive plug at the bottom and is exposed from the encapsulation layer at the top. Additionally, the top electrode 230 is so formed as to extend over the fifth conductive plug 230.

After that, referring to FIG. 4d, the substrate 300 is provided and etched so that the upper cavity 310 is formed therein. The substrate 300 is then bonded to the device wafer 100, resulting in the formation of the crystal resonator. Forming the crystal resonator in this way achieves integration of the crystal resonator with both the semiconductor die and the control circuit.

An integrated structure of a crystal resonator and a control circuit corresponding to the above method according to an embodiment will be described below with combined reference to FIGS. 2a to 2k and 3e. The structure includes:

a device wafer 100, in which the control circuit and a lower cavity 120 are formed, the lower cavity 120 having an opening at a back side of the device wafer, the control circuit optionally including interconnecting structures, at least some of which extend to a front side of the device wafer 100;

a substrate 300, which is bonded to the device wafer 100 from the back side thereof, and in which an upper cavity 310 is formed, the upper cavity 310 having an opening facing the device wafer 100, i.e., opposing the opening of the lower cavity 120;

a piezoelectric vibrator 500 comprising a bottom electrode 510, a piezoelectric crystal 520 and a top electrode 530, the piezoelectric vibrator 500 sandwiched between the device wafer 100 and the substrate 300 so that the lower and upper cavities 120, 310 are on opposing sides of the piezoelectric vibrator 500;

a first connecting structure electrically connecting both the top and bottom electrodes 530, 510 of the piezoelectric vibrator 500 to the control circuit;

a semiconductor die 700 bonded to the back side of the device wafer 100 or to the substrate 300, wherein in the semiconductor die 700, there is formed, for example, a drive circuit for producing an electrical signal to be transmitted to the piezoelectric vibrator 500 by the control circuit 100; and

a second connecting structure electrically connecting the semiconductor die 700 to the control circuit.

The semiconductor die 700 may be heterogeneous from the device wafer 100. That is, the semiconductor die may include a substrate made of a material different from that of the device wafer 100. For example, in this embodiment, differing from the device wafer 100 that is made of silicon, the substrate of the heterogeneous die may be formed of a Group III-V semiconductor material or a Group II-VI semiconductor material (specific examples include germanium, germanium silicon, gallium arsenide, etc.)

The lower cavity 120 in the device wafer 100 and the upper cavity 310 in the substrate 300 may be formed using planar fabrication processes, and the device wafer 100 and the substrate 300 may be bonded together so that the upper and lower cavities 120, 310 are in positional correspondence with each other on opposing sides of the piezoelectric vibrator 500. In this way, the piezoelectric vibrator 500 and the control circuit can be integrated on the same device wafer so that the control circuit can cause the piezoelectric vibrator 500 to oscillate within the upper and lower cavities 310, 120. In addition, the semiconductor die bonded to the device wafer 100 can enhance performance of the crystal resonator by on-chip modulation under the control of the control circuit 110 for correcting raw deviations of the crystal resonator such as temperature and frequency drifts. Thus, in addition to an enhanced degree of integration, the crystal resonator of the present invention fabricated using semiconductor processes are more compact in size and thus less power-consuming.

With continued reference to FIG. 2a, the control circuit may include first and second circuits 111, 112, which are electrically connected to the top and bottom electrodes of the piezoelectric vibrator 500, respectively.

Specifically, the first circuit 111 may include a first transistor, a first interconnecting structure 111a and a third interconnecting structure 111b. The first transistor may be buried within the device wafer 100, and the first and third interconnecting structures 111a, 111b may be both electrically connected to the first transistor and extend to the front side of the device wafer 100. The first interconnecting structure 111a may be electrically connected to the bottom electrode 510 and the third interconnecting structure 111b to the semiconductor die.

Similarly, the second circuit 112 may include a second transistor, a second interconnecting structure 112a and a fourth interconnecting structure 112b. The second transistor may be buried within the device wafer 100, and the second and fourth interconnecting structures 112a, 112b may be both electrically connected to the second transistor and extend to the front side of the device wafer 100. The second interconnecting structure 112a may be electrically connected to the top electrode 530 and the fourth interconnecting structure 112b may be electrically connected to the semiconductor die.

The first connecting structure may include a first connecting member and a second connecting member. The first connecting member may be connected to the first interconnecting structure 111a and the bottom electrode 510 of the piezoelectric vibrator. The second connecting member may be connected to the second interconnecting structure 112a and the top electrode 530 of the piezoelectric vibrator.

The first connecting member may include a first conductive plug 211a, which penetrates through the device wafer 100 so as to extend to the front side of the device wafer into electrical connection with the first interconnecting structure at one end and to extend to the back side of the device wafer 100 into electrical connection with the bottom electrode 510 of the piezoelectric vibrator 500 at the other end.

The first connecting member may further include a first connecting wire 221a. In this embodiment, the first connecting wire 221a is formed on the front side of the device wafer 100 and connects the first conductive plug 211a to the first interconnecting structure 111a. In alternative embodiments, the first connecting wire 221a may be formed on the back side of the device wafer 100 and connect the first conductive plug to the bottom electrode.

In this embodiment, the bottom electrode 510 is formed on the back side of the device wafer 100 around the lower cavity 120 and has an extension that laterally extends beyond the piezoelectric crystal 520 over the first conductive plug 211a, thus bringing the bottom electrode 210 into electrical connection with the first interconnecting structure 111a in the first circuit 111.

The second connecting member may include a second conductive plug 212a, which penetrates through the device wafer 100 so as to extend to the front side of the device wafer 100 into electrical connection with the second interconnecting structure at one end and to extend to the back side of the device wafer 100 into electrical connection with the top electrode 530 of the piezoelectric vibrator at the other end.

The second connecting member may further include a second connecting wire 222a. In this embodiment, the second connecting wire 222a is formed on the front side of the device wafer 100 and connects the second conductive plug 212a to the second interconnecting structure 112a. In alternative embodiments, the second connecting wire 222a may be formed on the back side of the device wafer 100 and connect the second conductive plug to the top electrode.

The second connecting member may further include a fifth conductive plug, which is electrically connected to the top electrode 530 at one end and to the second conductive plug 212a at the other end. For example, the top electrode may extend beyond the piezoelectric crystal over the end of the fifth conductive plug.

Specifically, an encapsulation layer may be arranged between the device wafer 100 and the substrate 300 such as to cover side surfaces of the piezoelectric crystal 220 and both the extensions of the top and bottom electrodes. The fifth conductive plug 230 in the second connecting member may extend through the encapsulation layer so as to be connected to the extension of the top electrode at one end and to the second conductive plug at the other end.

Of course, in other embodiments, the second connecting member may further include an interconnecting wire, which covers the top electrode 530 at one end and covers at least part of, and comes into connection with, the fifth conductive plug at the other end.

The second connecting structure may include conductive plugs and connecting wires. The conductive plugs in the second connecting structure may extend through the device wafer 100 to the front side of the device wafer 100 at one end and to the back side of the device wafer 100 at the other end. The ends of the conductive plugs reaching the back side of the device wafer 100 may be electrically connected to the semiconductor die 900. The connecting wires may be formed on the front side of the device wafer 100 and connect the conductive plugs to the control circuit.

With this arrangement, the conductive plugs and connecting wires collaboratively lead connection ports of the control circuit for electrically connecting the semiconductor die from the front to back side of the device wafer. In this way, the connection ports of the control circuit are allowed to be brought into electrical connection with the semiconductor die on the back side of the device wafer where the semiconductor die is bonded.

In this embodiment, the conductive plugs in the second connecting structure may include a third conductive plug 211b and a fourth conductive plugs 212b, and the connecting wires in the second connecting structure may include a first connecting wire 221b and a second connecting wire 222b. The third connecting wire 221b may connect the third conductive plug 211b to the third interconnecting structure 111b, and the fourth connecting wire 222b may connect the fourth conductive plug 212b to the fourth interconnecting structure 112b.

Moreover, in this embodiment, the semiconductor die 700 is bonded to the surface of the substrate 300 facing away from the device wafer 100. The second connecting structure may further include contact plugs, which extends through the substrate 300 and are electrically connected to the conductive plugs at the bottom and to the semiconductor die 700 at the top.

In this embodiment, the contact plugs in the second connecting structure may include a first contact plug 710 and a second contact plug 720. The first contact plug 710 may be electrically connected to the third interconnecting structure 111b at the bottom and to the semiconductor die 700 at the top. The second contact plug 720 may be electrically connected to the fourth interconnecting structure 112b at the bottom and to the semiconductor die 700 at the top.

With continued reference to FIG. 2a, in this embodiment, the device wafer 100 includes a substrate wafer 100A and a dielectric layer 100B. The first and second transistors may be both formed on the substrate wafer 100A, and the dielectric layer 100B may reside on the substrate wafer 100A and thus cover both the first and second transistors. The third, first, fourth and second interconnecting structures 111b, 111a, 112b, 112a may be all formed in the dielectric layer 100B and extend up to the surface of the dielectric layer 100B away from the substrate wafer 100A.

The semiconductor die 700 may be covered by an encapsulation layer formed on the substrate 300.

In this embodiment, the lower cavity 120 extends through the device wafer 100 and thus has another opening at the front side of the device wafer. Accordingly, a cap substrate may be optionally bonded to the front side of the device wafer to close the opening of the lower cavity present at the front side of the device wafer. The cap substrate may be composed of, for example, a silicon wafer.

In other embodiments, for example, as shown in FIG. 4d, the semiconductor die 700 may be bonded between the device wafer 100 and the substrate 300. In this case, the second connecting structure may include contact pads 710′ formed on the surface of the device wafer 100. The contact pads 710′ may be electrically connected to the control circuit at the bottom and to the semiconductor die 700 at the top.

In summary, in the method for integrating the crystal resonator with the control circuit according to the present invention, integration of the control circuit with the crystal resonator on the same device wafer is achieved by forming the lower cavity in the device wafer and the upper cavity in the substrate and employing a bonding process to bond the substrate to the device wafer in such a manner that the piezoelectric vibrator is sandwiched between the device wafer and the substrate, with the lower and upper cavities being in positional correspondence with each other on opposing sides of the piezoelectric vibrator. In addition, the semiconductor die containing, for example, a drive circuit may be bonded to the back side of the device wafer. In this way, all the semiconductor die, control circuit and crystal resonator are integrated on the same semiconductor substrate. This is favorable to on-chip modulation for correcting raw deviations of the crystal resonator such as temperature and frequency drifts. Compared with traditional crystal resonators (e.g., surface-mount ones), the proposed crystal resonator fabricated using planar fabrication processes is more compact in size and hence less power-consuming. Moreover, it is able to integrate with other semiconductor components more easily with a higher degree of integration.

The description presented above is merely that of a few preferred embodiments of the present invention without limiting the scope thereof in any sense. Any and all changes and modifications made by those of ordinary skill in the art based on the above teachings fall within the scope as defined in the appended claims.

1. A method for integrating a crystal resonator with a control circuit, comprising:
providing a device wafer in which the control circuit is formed;
forming, in the device wafer, a lower cavity with an opening at a back side of the device wafer;
providing a substrate and etching the substrate so that an upper cavity of the crystal resonator is formed therein in positional correspondence with the lower cavity;
forming a piezoelectric vibrator comprising a top electrode, a piezoelectric crystal and a bottom electrode, each of which is formed either on the back side of the device wafer or on the substrate;
forming a first connecting structure on the device wafer or on the substrate;
bonding the substrate to the back side of the device wafer such that the piezoelectric vibrator is positioned between the device wafer and the substrate, with the upper and lower cavities being located on opposing sides of the piezoelectric vibrator, and electrically connecting both the top and bottom electrodes of the piezoelectric vibrator to the control circuit through the first connecting structure; and
bonding a semiconductor die in a direction toward the back side of the device wafer and forming a second connecting structure electrically connecting the semiconductor die to the control circuit.

2. (canceled)

3. (canceled)

4. The method for integrating a crystal resonator with a control circuit claim 1, wherein the formation of the lower cavity comprises: etching the device wafer from a front side thereof to form the lower cavity for the crystal resonator; thinning the device wafer from the back side thereof to expose the lower cavity; and bonding a cap substrate to the front side of the device wafer so that the cap substrate covers and closes the opening of the lower cavity at the front side of the device wafer; or
wherein the formation of the lower cavity comprises etching the device wafer from the back side thereof to form the lower cavity for the crystal resonator.

5. The method for integrating a crystal resonator with a control circuit claim 4, wherein the device wafer comprises a silicon-on-insulator substrate comprising a base layer, a buried oxide layer and a top silicon layer, which are sequentially stacked from the back side to the front side of the device wafer, and
wherein the method further comprises, prior to forming the lower cavity by etching the device wafer from the back side thereof, removing the base layer and the buried oxide layer, and forming the lower cavity by etching the device wafer from the back side thereof comprises forming the lower cavity by etching the top silicon layer;
wherein the top electrode is formed on the substrate and the bottom electrode is formed on the back side of the device wafer, wherein each of the top and bottom electrodes is formed using a vapor deposition process or a thin-film deposition process, and wherein the piezoelectric crystal is bonded to the top or bottom electrode.

6. The method for integrating a crystal resonator with a control circuit claim 1, wherein the piezoelectric vibrator is formed on the back side of the device wafer or on the substrate, or wherein the bottom electrode of the piezoelectric vibrator is formed on the back side of the device wafer, and the top electrode and piezoelectric crystal of the piezoelectric vibrator are successively formed on the substrate, or wherein the bottom electrode and piezoelectric crystal of the piezoelectric vibrator are successively formed on the back side of the device wafer and the top electrode of the piezoelectric vibrator is formed on the substrate.

7. The method for integrating a crystal resonator with a control circuit claim 6, wherein forming the piezoelectric vibrator on the back side of the device wafer comprises: forming the bottom electrode at a predetermined position on the back side of the device wafer; bonding the piezoelectric crystal to the bottom electrode; and forming the top electrode on the piezoelectric crystal; or
forming the top and bottom electrodes of the piezoelectric vibrator on the piezoelectric crystal; and bonding the top electrode, the bottom electrode, and the piezoelectric crystal as a whole to the back side of the device wafer;
wherein the formation of the bottom electrode comprises a vapor deposition process or a thin-film deposition process, and wherein the formation of the top electrode comprises a vapor deposition process or a thin-film deposition process;
wherein forming the piezoelectric vibrator on the substrate comprises:
forming the top electrode at a predetermined position on a surface of the substrate; bonding the piezoelectric crystal to the top electrode; and forming the bottom electrode on the piezoelectric crystal; or
forming the top and bottom electrodes of the piezoelectric vibrator on the piezoelectric crystal; and bonding the top electrode, the bottom electrode, and the piezoelectric crystal as a whole to the substrate;
wherein the formation of the bottom electrode comprises a vapor deposition process or a thin-film deposition process, and wherein the formation of the top electrode comprises a vapor deposition process or a thin-film deposition process.

8. (canceled)

9. (canceled)

10. (canceled)

11. (canceled)

12. The method for integrating a crystal resonator with a control circuit claim 1, wherein the control circuit comprises a first interconnecting structure and a second interconnecting structure, and the connecting structure comprises a first connecting member and a second connecting member, and wherein the first connecting member connects the first interconnecting structure to the bottom electrode of the piezoelectric vibrator, and the second connecting member connects the second interconnecting structure to the top electrode of the piezoelectric vibrator;
wherein the first connecting member is formed prior to the formation of the bottom electrode, and wherein:
the first connecting member comprises a first conductive plug in the device wafer, the first conductive plug electrically connected at opposing ends thereof respectively to the first interconnecting structure and the bottom electrode; or
the first connecting member comprises a first conductive plug in the device wafer and a first connecting wire on the back side of the device wafer, the first connecting wire electrically connected to one end of the first conductive plug, the first conductive plug electrically connected at a further end to the first interconnecting structure, the first connecting wire electrically connected to the bottom electrode; or
the first connecting member comprises a first conductive plug in the device wafer and a first connecting wire on a front side of the device wafer, the first connecting wire electrically connected to one end of the first conductive plug, the first conductive plug electrically connected at a further end to the bottom electrode, the first connecting wire electrically connected to the first interconnecting structure;
wherein the second connecting member is formed prior to the formation of the top electrode, and wherein:
the second connecting member comprises a second conductive plug in the device wafer, the second conductive plug electrically connected at opposing ends thereof respectively to the second interconnecting structure and the top electrode; or
the second connecting member comprises a second conductive plug in the device wafer and a second connecting wire on the back side of the device wafer, the second connecting wire electrically connected to one end of the second conductive plug, the second conductive plug electrically connected at a further end to the second interconnecting structure, the second connecting wire electrically connected to the top electrode; or
the second connecting member comprises a second conductive plug in the device wafer and a second connecting wire on the front side of the device wafer, the second connecting wire electrically connected to one end of the second conductive plug, the second conductive plug electrically connected at a further end to the top electrode, the second connecting wire electrically connected to the second interconnecting structure.

13. The method for integrating a crystal resonator with a control circuit claim 12, wherein the formation of the first connecting member comprising the first conductive plug and the first connecting wire on the front side of the device wafer comprises:
forming a first connecting hole by etching the device wafer from the front side thereof;
filling a conductive material in the first connecting hole to form the first conductive plug;
forming the first connecting wire on the front side of the device wafer, the first connecting wire connecting the first conductive plug to the first interconnecting structure; and
thinning the device wafer from the back side thereof so that the first conductive plug is exposed and becomes available for electrical connection to the bottom electrode of the piezoelectric vibrator; or
wherein the formation of the first connecting member comprising the first conductive plug and the first connecting wire on the front side of the device wafer comprises:
forming the first connecting wire on the front side of the device wafer, the first connecting wire electrically connected to the first interconnecting structure;
thinning the device wafer from the back side thereof and forming a first connecting hole by etching the device wafer from the back side thereof, the first connecting hole extending through the device wafer so that the first connecting wire is exposed in the first connecting hole; and
filling a conductive material in the first connecting hole to form the first conductive plug, the first conductive plug connected at one end to the first connecting wire, a further end of the first conductive plug available for electrical connection to the bottom electrode of the piezoelectric vibrator;
wherein the formation of the second connecting member comprising the second conductive plug and the second connecting wire on the front side of the device wafer comprises:
forming a second connecting hole by etching the device wafer from the front side thereof;
filling a conductive material in the second connecting hole to form the second conductive plug;
forming the second connecting wire on the front side of the device wafer, the second connecting wire connecting the second conductive plug to the second interconnecting structure; and
thinning the device wafer from the back side thereof so that the second conductive plug is exposed and becomes available for electrical connection to the top electrode of the piezoelectric vibrator; or
wherein the formation of the second connecting member comprising the second conductive plug and the second connecting wire on the front side of the device wafer comprises:
forming the second connecting wire on the front side of the device wafer, the second connecting wire electrically connected to the second interconnecting structure;
thinning the device wafer from the back side thereof and forming a second connecting hole by etching the device wafer from the back side thereof, the second connecting hole extending through the device wafer so that the second connecting wire is exposed in the second connecting hole; and
filling a conductive material in the second connecting hole to form the second conductive plug, the second conductive plug connected at one end to the second connecting wire, a further end of the second conductive plug available for electrical connection to the top electrode of the piezoelectric vibrator.

14. The method for integrating a crystal resonator with a control circuit claim 12, wherein the formation of the first connecting member comprising the first conductive plug and the first connecting wire on the back side of the device wafer comprises:
forming a first connecting hole by etching the device wafer from the front side thereof;
filling a conductive material in the first connecting hole to form the first conductive plug, the first conductive plug electrically connected to the first interconnecting structure;
thinning the device wafer from the back side thereof so that the first conductive plug is exposed; and
forming the first connecting wire on the back side of the device wafer, the first connecting wire connected at one end to the first conductive plug, a further end of the first connecting wire available for electrical connection to the bottom electrode; or
wherein the formation of the first connecting member comprising the first conductive plug and the first connecting wire on the back side of the device wafer comprises:
thinning the device wafer from the back side thereof and forming a first connecting hole by etching the device wafer from the back side thereof,
filling a conductive material in the first connecting hole to form the first conductive plug, the first conductive plug electrically connected at one end to the first interconnecting structure; and
forming the first connecting wire on the back side of the device wafer, the first connecting wire connected at one end to a further end of the first conductive plug, the further end of the first connecting wire available for electrical connection to the bottom electrode;
wherein the formation of the second connecting member comprising the second conductive plug and the second connecting wire on the back side of the device wafer comprises:
forming a second connecting hole by etching the device wafer from the front side thereof;
filling a conductive material in the second connecting hole to form the second conductive plug, the second conductive plug electrically connected to the second interconnecting structure;
thinning the device wafer from the back side thereof so that the second conductive plug is exposed; and
forming the second connecting wire on the back side of the device wafer, the second connecting wire connected at one end to the second conductive plug, a further end of the second connecting wire available for electrical connection to the top electrode; or
wherein the formation of the second connecting member comprising the second conductive plug and the second connecting wire on the back side of the device wafer comprises:
thinning the device wafer from the back side thereof and forming a second connecting hole by etching the device wafer from the back side thereof,
filling a conductive material in the second connecting hole to form the second conductive plug, the second conductive plug electrically connected at one end to the second interconnecting structure; and
forming the second connecting wire on the back side of the device wafer, the second connecting wire connected at one end to a further end of the second conductive plug, the further end of the second connecting wire available for electrical connection to the top electrode.

15. The method for integrating a crystal resonator with a control circuit claim 12, wherein the bottom electrode is formed on the back side of the device wafer, and extends beyond the piezoelectric crystal thereunder to come into electrical connection with the first conductive plug.

16. (canceled)

17. (canceled)

18. (canceled)

19. The method for integrating a crystal resonator with a control circuit claim 12, wherein the piezoelectric crystal is formed on the back side of the device wafer, and wherein the formation of the second connecting member further comprises, prior to the formation of the top electrode on the device wafer:
forming an encapsulation layer on the back side of the device wafer; and
forming a through hole in the encapsulation layer and filling a conductive material in the through hole to form a fifth conductive plug, the fifth conductive plug electrically connected at a bottom thereof to the second conductive plug, the fifth conductive plug exposed at a top thereof from the encapsulation layer, and
wherein the top electrode is formed on the device wafer, and extends beyond the piezoelectric crystal over the fifth conductive plug to come into electrical connection with the fifth conductive plug; or subsequent to the formation of the top electrode on the device wafer, an interconnecting wire is formed on the encapsulation layer, the interconnecting wire extending over the top electrode at one end and over the fifth conductive plug at a further end; or
wherein the top electrode and the piezoelectric crystal are successively formed on the substrate, and wherein the formation of the second connecting member further comprises, prior to the bonding of the substrate to the device wafer;
forming an encapsulation layer on the surface of the substrate;
forming a through hole in the encapsulation layer, in which the top electrode is exposed, and filling a conductive material in the through hole to form a fifth conductive plug, the fifth conductive plug electrically connected to the top electrode at one end; and
bringing the fifth conductive plug into electrical connection with the second interconnecting structure at the further end as a result of bonding the substrate to the device wafer.

20. (canceled)

21. The method for integrating a crystal resonator with a control circuit claim 1, wherein the formation of the second connecting structure comprises:
forming connecting holes by etching the device wafer from the front side thereof;
forming a conductive plug by filling a conductive material in the connecting holes;
forming connecting wires on a front side of the device wafer, which are connected to the conductive plug and the control circuit; and
thinning the device wafer from the back side until the conductive plug is exposed and become available for electrical connection with the semiconductor die; or
wherein the formation of the second connecting structure comprises:
forming connecting wires on a front side of the device wafer, which are electrically connected to the control circuit;
etching the device wafer from the back side thereof so that connecting holes are formed therein, which extend through the device wafer, and in which the respective connecting wires are exposed; and
filling a conductive material in the connecting holes so that conductive plug is formed to be connected to the connecting wires at one end and configured for electrical connection with the semiconductor die at a further end.

22. (canceled)

23. (canceled)

24. The method for integrating a crystal resonator with a control circuit claim 21, wherein the semiconductor die is bonded to the substrate after the substrate is bonded to the device wafer, and wherein the formation of the second connecting structure further comprises:
etching the substrate to form a contact hole therein prior to the bonding of the semiconductor die; and
forming a contact plug by filling a conductive material in the contact hole, the contact plug electrically connected at a bottom thereof to the conductive plug and available for electrical connection at a top thereof with the semiconductor die; or
wherein the semiconductor die is bonded to the substrate before the substrate is bonded to the device wafer, and wherein the formation of the second connecting structure further comprises: prior to the formation of the semiconductor die, forming a contact pad on the back side of the device wafer, the contact pad electrically connected at a bottom thereof to the conductive plug and at a top thereof to the semiconductor die.

25. (canceled)

26. (canceled)

27. (canceled)

28. The method for integrating a crystal resonator with a control circuit claim 1, wherein the top electrode and piezoelectric crystal of the piezoelectric vibrator are successively formed on the substrate, and wherein
the bonding of the device wafer and the substrate comprising:
applying an adhesive layer to the substrate so that a surface of the piezoelectric crystal is exposed from the adhesive layer; and
bonding the device wafer and the substrate together by means of the adhesive layer; or
wherein the bottom electrode and piezoelectric crystal of the piezoelectric vibrator are successively formed on the device wafer, and wherein
the bonding of the device wafer and the substrate comprising:
applying an adhesive layer to the device wafer so that a surface of the piezoelectric crystal is exposed from the adhesive layer; and
bonding the device wafer and the substrate together by means of the adhesive layer.

29. (canceled)

30. An integrated structure of a crystal resonator and a control circuit, comprising: a device wafer in which the control circuit and a lower cavity are formed, the lower cavity having an opening at a back side of the device wafer;
a substrate, which is bonded to the device wafer from the back side thereof, and in which an upper cavity is formed, the upper cavity having an opening arranged in opposition to the opening of the lower cavity;
a piezoelectric vibrator comprising a top electrode, a piezoelectric crystal and a bottom electrode, the piezoelectric vibrator arranged between the device wafer and the substrate so that the lower and upper cavities are on opposing sides of the piezoelectric vibrator;
a first connecting structure electrically connecting the top and bottom electrodes of the piezoelectric vibrator to the control circuit;
a semiconductor die bonded to the back side of the device wafer or to the substrate; and
a second connecting structure electrically connecting the semiconductor die to the control circuit.

31. (canceled)

32. The integrated structure of a crystal resonator and a control circuit claim 30, wherein the control circuit comprises a first interconnecting structure and a second interconnecting structure, and the connecting structure comprises a first connecting member and a second connecting member,
wherein the first connecting member connects the first interconnecting structure to the bottom electrode of the piezoelectric vibrator, the second connecting member connects the second interconnecting structure to the top electrode of the piezoelectric vibrator.

33. The integrated structure of a crystal resonator and a control circuit claim 32, wherein the first connecting member comprises
a first conductive plug, which extends through the device wafer so that one end of the first conductive plug is located at a front side of the device wafer and a further end of the first conductive plug is located at the back side of the device wafer and electrically connected to the bottom electrode of the piezoelectric vibrator;
wherein the second connecting member comprises
a second conductive plug, which extends through the device wafer so that one end of the second conductive plug extends to a front side of the device wafer to be electrically connected to the second interconnecting structure and a further end of the conductive plug extends to the back side of the device wafer to be electrically connected to the top electrode of the piezoelectric vibrator.

34. The integrated structure of a crystal resonator and a control circuit claim 33, wherein the first connecting member further comprises a first connecting wire, and wherein:
the first connecting wire is formed on the front side of the device wafer and connects the first conductive plug to the first interconnecting structure; or
the first connecting wire is formed on the back side of the device wafer and connects the first conductive plug to the bottom electrode;
and wherein the second connecting member further comprises a second connecting wire, and wherein:
the second connecting wire is formed on the front side of the device wafer and connects the second conductive plug to the second interconnecting structure, or
the second connecting wire is formed on the back side of the device wafer and connects the second conductive plug to the top electrode.

35. The integrated structure of a crystal resonator and a control circuit claim 33, wherein the bottom electrode is formed on the back side of the device wafer and extends beyond the piezoelectric crystal to come into electrical connection with the first conductive plug; wherein the second connecting member further comprises:
a fifth conductive plug formed on the back side of the device wafer, the fifth conductive plug electrically connected to the top electrode at one end and to the second conductive plug at a further end.

36. (canceled)

37. (canceled)

38. (canceled)

39. The integrated structure of a crystal resonator and a control circuit claim 32, wherein the second connecting member comprises
a second conductive plug, which extends through the device wafer so that one end of the second conductive plug extends to a front side of the device wafer to be electrically connected to the second interconnecting structure and a further end of the conductive plug extends to the back side of the device wafer to be electrically connected to the top electrode of the piezoelectric vibrator;
wherein the second connecting member further comprises:
a fifth conductive plug formed on the back side of the device wafer, the fifth conductive plug electrically connected at a bottom thereof to the second conductive plug;
an interconnecting wire, which covers the top electrode at one end and cover the fifth conductive plug at a further end.

40. The integrated structure of a crystal resonator and a control circuit claim 30, wherein the semiconductor die is bonded to a surface of the substrate away from the device wafer, and wherein the second connecting structure comprises:
a conductive plug, which extend through the device wafer so that one end of the conductive plug is located at a front side of the device wafer and a further end of the conductive plug is located at the back side and electrically connected to the semiconductor die;
a connecting wire formed on the front side of the device wafer, the connecting wire electrically connecting the conductive plug to the control circuit; and
a contact plug, which extends through the substrate so as to be electrically connected at a bottom thereof to the conductive plug and at a top thereof to the semiconductor die; or
wherein the semiconductor die is bonded between the device wafer and the substrate, and wherein the second connecting structure comprises:
a conductive plug, which extend through the device wafer so that one end of the conductive plug is located at a front side of the device wafer and a further end of the conductive plug is located at the back side and electrically connected to the semiconductor die;
a connecting wire formed on the front side of the device wafer, the connecting wire electrically connecting the conductive plug to the control circuit; and
a contact pad formed on the back side of the device wafer, the contact pad electrically connected at a bottom thereof to the conductive plug and at a top thereof to the semiconductor die.

41. (canceled)

42. (canceled)

43. (canceled)

44. (canceled)
